(19) United States
(12) Patent Application Publication
(10) Pub. No.: US 2025/0335683 A1
(43) Pub. Date: Oct. 30, 2025

(54) SECURE SOLUTIONS FOR RESOURCE-RESTRICTIONS ON INTEGRATED CIRCUITS

(71) Applicant: XILINX, INC., San Jose, CA (US)

(72) Inventors: David P. SCHULTZ, Seattle, WA (US); Felix BURTON, Foster City, CA (US)

(21) Appl. No.: 18/649,642

(22) Filed: Apr. 29, 2024

(51) Int. Cl. G06F 30/337

(52) U.S. Cl. CPC G06F 30/337

(57) ABSTRACT

Embodiments herein describe secure solutions for resource-restrictions on integrated circuits. In an example, dedicated compliance circuitry monitors resource metrics of functional circuitry over dedicated communication infrastructure based on a hardware-embedded authentication metric, and performs a remedial action if the resource metrics exceed resource restrictions (e.g., disables the functional circuitry). The compliance circuitry may include a dedicated processor, non-reprogrammable storage circuitry encoded with first instructions and the authentication metric, and reprogrammable storage circuitry encoded with second instructions. The processor executes the first instructions on power-up. The first instructions cause the processor to authenticate the second instructions based on the authentication metric, and execute the second instructions if the second instructions are authenticated. The second instructions cause the processor to monitor the resource metric and perform the remedial action. The second instructions may be modified but will not pass authentication if the modification is not encoded based on the authentication metric.

### TECHNICAL FIELD

Examples of the present disclosure generally relate to secure solutions for resource-restrictions on integrated circuits.

### BACKGROUND

National governments, including the U.S. government, place export restrictions on certain technologies. With respect to integrated circuit (IC) devices, export restrictions may include environment-based restrictions (e.g., restrictions on temperature and/or radiation levels in which an IC device is able to operate), and/or resources of the IC device.

Resource restrictions may force an IC designer/manufacturer to forego exporting an IC device, or to design/manufacture one or more reduced-resource versions of the IC device for export. Both solutions may negatively impact profits of the designer/manufacture.

### SUMMARY

Secure solutions for resource-restrictions on integrated circuits are described. One example is a system that includes functional circuitry and compliance circuitry that monitors a resource metric of the functional circuitry and performs a remedial action if the resource metric exceeds a resource restriction, based on a hardware-embedded authentication metric.

Another example described herein is a system that includes a processor, non-reprogrammable storage circuitry encoded with first instructions and an authentication metric, and reprogrammable storage circuitry encoded with second instructions, where the processor executes the first instructions from the non-reprogrammable storage circuitry when the processor is powered-up. The first instructions, when executed by the processor, cause the processor to authenticate the second instructions based on the authentication metric, and execute the second instructions from the reprogrammable storage circuitry if the processor authenticates the second instructions. The second instructions, when executed by the processor, cause the processor to monitor a resource metric of functional circuitry and perform a remedial action if the monitored resource metric exceeds a resource restriction.

Another example described herein is method that includes monitoring a resource metric of functional circuitry by compliance circuitry based on a hardware-embedded authentication metric, and performing a remedial action, by the compliance circuitry, if the monitored resource metric exceeds a resource restriction.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a block diagram of a system that includes functional circuitry and compliance circuitry, according to an embodiment.

FIG. 2 is block diagram of another system that includes functional circuitry and compliance circuitry, according to an embodiment.

FIG. 3 is a block diagram of another system that includes functional circuitry and compliance circuitry, according to an embodiment.

FIG. 4 illustrates a method 400, according to an embodiment.

FIG. 5 is a block diagram of configurable circuitry that includes an array of configurable or programmable circuit blocks or tiles, according to an embodiment.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Embodiments herein describe secure solutions for resource-restrictions on integrated circuits.

Resource restrictions may relate to, for example and without limitation, sample rates, data rates, operating frequency, toggle frequency, execution time, gate counts, device counts, total processing performance (TPP), and/or performance density. Resource restrictions may include per-function resource restrictions and/or aggregate resource restrictions. As an example, a per-function resource restriction may restrict a sample rate of an analog-to digital converter (ADC). As another example, an aggregate resource restriction may restrict an aggregate data rate of multiple transceivers.

An integrated circuit (IC) device that would otherwise exceed a resource restriction may be modified to comply with export restrictions, via software (e.g., a computer program executing on a management processor) or via electronic fuses (i.e., eFuses). Software-based approaches may be susceptible to malicious attack. eFuses are permanent but do not adequately address some types of resource restrictions, such as aggregate resource restrictions.

As an example, an export-control regulation may prohibit export of a field-programmable gate array (FPGA) having an aggregate one-way peak serial data rate of greater than 500 gigabits/second (Gb/s). An FPGA may have, for example, 128 transmit lanes, each capable of operating between 1.25 Gb/s and 224 Gb/s. If all 128 lanes run at 1.25 Gb/s, the aggregate data rate is 160 Gb/s, which is under the 500 Gb/s aggregate threshold. If, however, all 128 lanes run at 224 Gb/s, the aggregate data rate is over 28 terabits per second (Tb/s), which is well above the 500 Gb/s aggregate threshold. In order to ensure compliance with the 500 Gb/s aggregate threshold, an eFuse-based approach would need to permanently disable all but two of the 128 transceivers. Permanently disabling a significant number of the transceivers may, however, render the IC device unsuitable for an intended and permissible use, such as where the IC device is to communicate with more than two other devices.

Secure solutions for resource-restrictions on integrated circuits, as disclosed herein, may include a dedicated compliance circuitry that monitors resource metrics of functional circuitry, over a dedicated communication path, based on a hardware-embedded (i.e., permanent/unalterable) authentication metric that is inaccessible to the functional circuitry and inaccessible to a user. The compliance circuitry may perform a remedial action if the monitored resource metric exceeds a resource restriction, such as disabling at least a portion of the functional circuitry. The compliance circuitry may perform an authentication process based on the authentication metric, and may preclude operation of the functional circuitry until/unless the authentication process succeeds. The functional circuitry may include multiple circuit blocks that communicate with one another over a first communication infrastructure, and the compliance circuitry may monitor the resource metric over a second, dedicated, communication infrastructure.

In an example, the compliance circuitry includes a dedicated processor, non-reprogrammable storage circuitry encoded with first instructions and the authentication metric, and reprogrammable storage circuitry encoded with second instructions. The processor may be designed to execute the first instructions from the non-reprogrammable storage circuitry when the processor is powered-up. The first instructions, when executed by the processor, cause the processor to authenticate the second instructions based on the authentication metric, and to execute the second instructions from the reprogrammable storage circuitry if the processor authenticates the second instructions. The second instructions, when executed by the processor, cause the processor to monitor a resource metric of functional circuitry and perform a remedial action if the monitored resource metric exceeds a resource restriction.

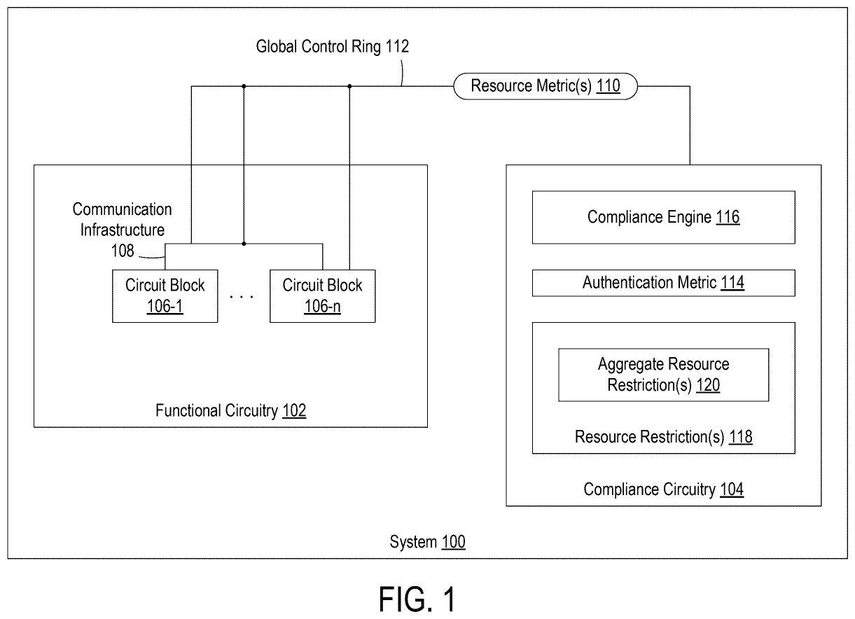

FIG. 1 is a block diagram of a system 100 that includes functional circuitry 102 and compliance circuitry 104, according to an embodiment. System 100 may represent a single integrated circuit (IC) die, multiple IC dies (e.g., chiplets, a chip set, an IC device that includes multiple stacked IC dies), a system-on-chip (SoC), a circuit card, one or more field-programmable gate arrays (FPGAs), a computer system (e.g., a server), and or multiple computers (e.g., a server farm).

Functional circuitry 102 may include multiple circuit blocks, 106-1 through 106-n (collectively, circuit blocks 106), two or more of which may communicate with one another over communication infrastructure 108. Circuit blocks 106 may include, without limitation, combinational logic, sequential logic, programmable logic (e.g., an FPGA), a processor(s), memory, digital processing elements (DPEs), artificial intelligence processing elements (AIEs), and/or input/output (IO) elements, such as analog-to-digital converters (ADCs), digital-to-analog converters (DACs), and/or transceivers. Communication infrastructure 108 may include intra-die communication infrastructure, inter-die communication infrastructure, serial communication infrastructure, bus-based communication infrastructure, packet-based communication infrastructure, such as a network-on-chip (NoC), and/or management controller communication infrastructure, which may include a configuration memory interface infrastructure for programming configuration memory of programmable circuitry.

Compliance circuitry 104 may monitor one or more resource metrics 110 of functional circuitry 102 over a dedicated, secure, communication infrastructure, illustrated here as a global control ring 112. Alternatively, or additionally, compliance circuitry 104 may monitor resource metric(s) 110 over another communication interface, such as a communication infrastructure of a management controller and/or communication infrastructure 108. Compliance circuitry 104 may retrieve or pull (e.g., read) a resource metric 110 from functional circuitry 102. Alternatively, or additionally, an element of functional circuitry 102 may provide or push a resource metric 110 to compliance circuitry 104.

Compliance circuitry 104 may include a compliance engine 116 that performs resource monitoring and compares resource metric(s) 110 to one or more resource restrictions 118. Compliance engine 116 may include, for example and without limitation a processor and/or a state machine. Resource restriction(s) 118 may include aggregate resource restriction(s) 120, and compliance engine 116 may aggregate multiple instances of a resource metric 110 (e.g., data rates of multiple transceivers), for comparison to an aggregate resource restriction 120.

Resource restriction(s) 118 may relate to, without limitation, sample rates, data rates, operating frequency, toggle frequency, execution time, gate counts, device counts, total processing performance (TPP), and/or performance density. A resource metric, such as (TPP) and/or performance density, may relate to processing elements/tiles, such as DPEs and/or AIEs, and may be defined by regulation. As an example, TPP may be defined as 2×MacTOPS×bit length of an operation, aggregated over all processing units on an integrated circuit, where MacTOPS is the theoretical peak number of Tera (10¹²) operations per second for multiply-accumulate computation (D=A×B+C), and performance density may equal TPP divided by an applicable die area. Resource restriction are not, however, limited to the foregoing examples. Resource restriction(s) 118 may relate to enabled/disabled regions of functional circuitry, such as regions of logic and/or memory, and/or levels of a multi-level IC device (e.g., a 3-dimensional IC device), and/or chiplets integrated on an interposer or substrate.

Resource metrics 110 may include, without limitation, sample rates, data rates, frame rates, operating frequency, toggle frequency, execution time, gate counts, and/or enabled element counts (e.g., input/output elements and/or processing elements/tiles), and/or enabled elements per region. Resource metrics 110 may be determined or selected based on resource restriction(s) 118.

In FIG. 1, compliance circuitry 104 further includes an authentication metric 114, which may be embedded in hardware such that authentication metric 114 is permanent/unalterable, inaccessible to functional circuitry 102, and inaccessible to a user. Compliance engine 116 may use authentication metric 114 to authenticate one or more features/elements of compliance circuitry 104, examples of which are provided further below.

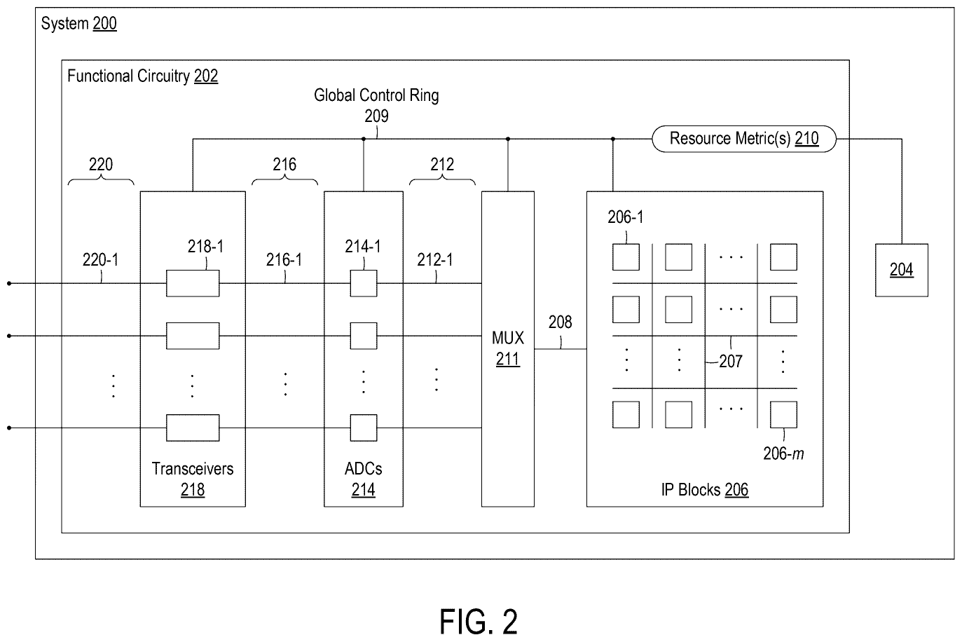

Functional circuitry 102 may include one or more features described below with reference to FIG. 2. Functional circuitry 102 is not limited to the example of FIG. 2. FIG. 2 is block diagram of a system 200 that includes functional circuitry 202 and compliance circuitry 204 that monitors a resource metric(s) 210 of functional circuitry 202 over a global control ring 209, according to an embodiment. System 200 may represent and/or may include a field-programmable gate array (FPGA). As an example, functional circuitry 202, compliance circuitry 204, or a portion thereof, may be programmed in an FPGA. System 200 is not, however, limited to an FPGA.

In FIG. 2, functional circuitry 202 includes multiple circuit blocks, illustrated here as IP blocks 206-1 through 206-m (collectively, IP blocks 206). IP blocks 206 may include one or more features described above with respect to circuit blocks 106 in FIG. 1. IP blocks 206 may represent, for example and without limitation, an array of DPEs and or AIEs. IP blocks 206 may be implemented in one or more FPGA, and/or may represent respective FPGAs. IP blocks 206 are not, however, limited to FPGAs. Two or more IP blocks 206 may communicate with one another over internal links 207, which may represent intra-die links and/or inter-die links. One or more IP blocks 206 may output data over a link(s) 208. The data may include serial and/or parallel data, and link(s) 208 may include one or more serial links and/or one or more buses.

In FIG. 2, functional circuitry 202 may further include multiplexer circuitry 211 that multiplexes data from link(s) 208. Multiplexer circuitry 211 may be useful in a situation where a number of IP blocks 206 that output data over link(s) 208 exceeds a number of available transmitters. Multiplexer circuitry 211 outputs multiplexed data over links 212.

Functional circuitry 202 may further include analog-to-digital converters (ADCs) 214 that serialize data received over links 212, and output serialized data over links 216.

Functional circuitry 202 further includes transceivers 218 that transmit serialized data from links 216 over respective links 220.

In FIG. 2, a first transmit lane may be defined to include a link 212-1, an ADC 214-1, a link 216-1, transmit circuitry of a transceiver 218-1, and an output link 220-1. Receive lane circuitry is not illustrated in FIG. 2.

Links 207, 208, 212, 216, and 220 may, collectively, represent an example of communication infrastructure 108 in FIG. 1. Functional circuitry 202 may include additional communication infrastructure, such as receive lane communication infrastructure and/or management controller communication infrastructure, and compliance circuitry 204 may be configured to monitor resource parameters of such additional communication infrastructure.

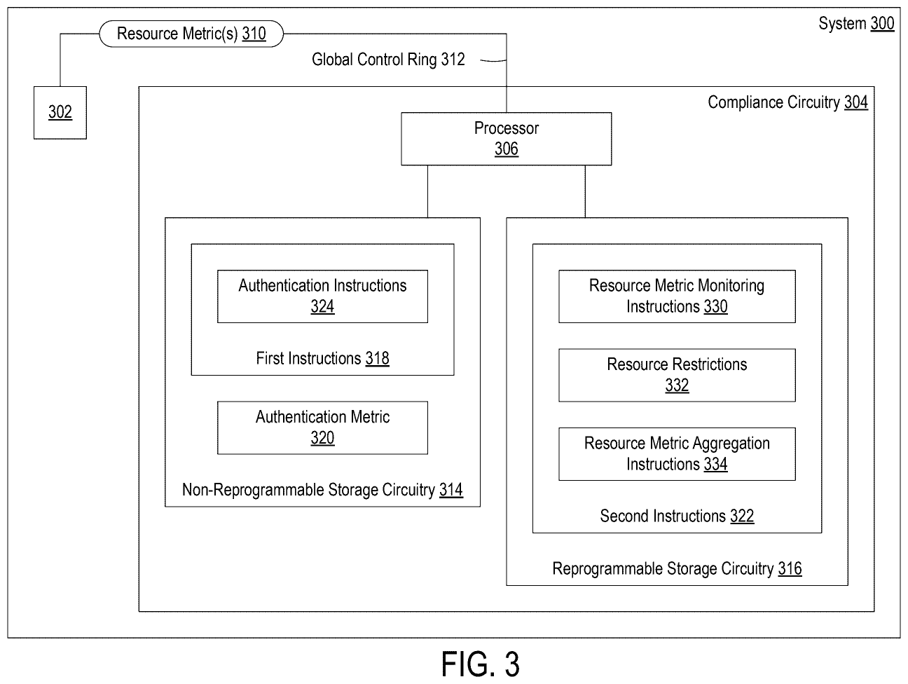

Examples of compliance circuitry 104 and 204 are provided below with reference to FIG. 3. Compliance circuitry 104 and 204 are not, however, limited to the example of FIG. 3. FIG. 3 is a block diagram of a system 300 that includes functional circuitry 302 and compliance circuitry 304, according to an embodiment. Compliance circuitry 304 includes a processor 306, non-reprogrammable storage circuitry 314, and reprogrammable storage circuitry 316.

Non-reprogrammable storage circuitry 314 may include, without limitation, read-only-memory (ROM), such as mask-programmed ROM, one-time-programmable ROM (PROM), and/or eFuses. Non-reprogrammable storage circuitry 314 may be encoded with first instructions 318 and an authentication metric 320. First instructions 318 and authentication metric 320 may be encoded within non-reprogrammable storage circuitry 314 by a manufacturer or vendor and, once encoded, may be un-alterable, and may be un-readable/inaccessible except by processor 306. Processor 306 may be configured to execute first instructions 318 upon power-on of processor 306 (i.e., when power is provided to processor 306).

Reprogrammable storage circuitry 316 may include, without limitation, reprogrammable ROM such as electrically erasable programmable read-only memory (EEPROM). In the example of FIG. 3, reprogrammable storage circuitry 316 is encoded with second instructions 322.

First instructions 318 may include authentication instructions 324 that, when executed by processor 306, cause processor 306 to authenticate second instructions 322 based on authentication metric 320. Authentication metric 320 may include a value (e.g., fingerprint or a hash key/value), and authentication instructions 324 may cause processor 306 to compute a value (e.g., based on a hash function) based on second instructions 322, and compare the computed value to authentication metric 320. In another example, authentication instructions 324 may cause processor 306 to compute a first value based on authentication metric 320, compute a second value based on second instructions 322, and compare the first and second values. Authentication instructions 324 are not, however, limited to the foregoing examples.

Second instructions 322 may include resource metric monitoring instructions 330 and resource restrictions 332. Second instructions 322 may further include resource metric aggregation instructions 334. Resource metric monitoring instructions 330, when executed by processor 306, cause processor 306 to monitor resource metric(s) 310 of functional circuitry 302 over a global control ring 312, and perform a remedial action if resource metric(s) 310 exceeds resource restrictions 332. Resource metric aggregation instructions 334, when executed by processor 306, cause processor 306 to aggregate resource metric(s) 310 for comparison to an aggregate resource restriction 332.

In an example, while first instructions 318 and authentication metric 320 are encoded in non-reprogrammable storage circuitry 314, second instructions 322 may be accessible to a user, such as to permit the user to alter (e.g., add, omit, and/or change) resource restrictions 332 and/or metrics to be monitored. However, if second instructions 322 are altered, the altered second instructions must be encoded within reprogrammable storage circuitry 316 based on authentication metric 320, such that processor 306 will successfully authenticate the altered second instructions. In other words, second instructions 322 cannot be altered without access to authentication metric 320 (or a source of authentication metric 320). If second instructions 322 are altered without being properly encoded based authentication metric 320, processor 306 may not proceed to execute second instructions 322, and compliance circuitry 304 may disable functional circuitry 302 or a portion thereof. In the foregoing example, alteration of second instructions 322 may need to be performed in cooperation with and/or acquiescence an entity (e.g., manufacture, vendor and/or government agent) that has access to authentication metric 320 or a source of authentication metric 320). Under the foregoing example, resource restrictions 332 and/or source code of second instructions 322 may be disclosed to a user and/or may be publicly disclosed, within impacting security of compliance circuitry 304. Disclosure of resource restrictions 332 and/or the source code of second instructions 322 may be useful to provide a user with confidence that compliance circuitry 304 will not perform undeclared functions.

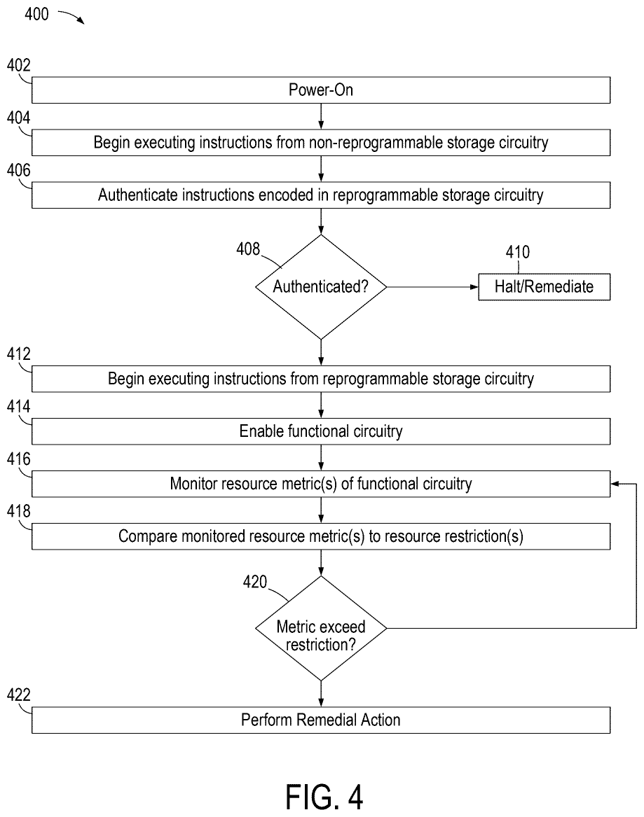

FIG. 4 illustrates a method 400, according to an embodiment. Method 400 is described below with reference to the examples of FIGS. 1-3. Method 400 is not, however, limited to the examples of FIGS. 1-3.

At 402, power is applied to compliance circuitry 304. In an example, system 300 is designed such that, when power is applied to system 300, the power is initially provided to compliance circuitry 304, and compliance circuitry 304 determines whether to provide power to functional circuitry 302. In another example, system 300 is further designed such that, when power is applied to system 300, the power is initially provided to a management controller of system 300 and, upon completion of one or more management tasks, the management controller enables power to compliance circuitry 304.

At 404, when processor 306 turns on, processor 306 begins executing first instructions 318. Processor 306 may be provided (e.g., pre-programmed) with a pointer to a beginning address of first instructions 318 within non-reprogrammable storage circuitry 314. Processor 306 may read and execute first instructions 318 directly from non-reprogrammable storage circuitry 314, or may copy first instructions 318 to a relatively block of random-access-memory (RAM) of compliance circuitry 304 and execute first instructions 318 from the RAM.

At 406, processor 306 performs an authentication procedure based on authentication instructions 324 and authentication metric 320. In an example, authentication metric 320 includes a value (e.g., fingerprint or a hash key/value). In this example, processor 306 may compute a value based on second instructions 322, and compare the computed value to authentication metric 320. Processor 306 may compute the value based on, for example, a hash function. In another example, processor 306 computes a first value based on authentication metric 320, computes a second value based on second instructions 322, and compares the first and second computed values. The authentication procedure is not, however, limited to the foregoing examples.

At 408, if processor 306 successfully authenticates second instructions 322, processing proceeds to 412, where processor 306 begins executing second instructions 322. If processor 306 does not successfully authenticate second instructions 322, processing proceeds to 410. In an example, authentication instructions 324 includes “if/then/else” instructions that direct/point processor 306 to second instructions 322 if processor successfully authenticates second instructions 322, and that otherwise cause processor 306 to halt or interrupt further processing and/or initiate remedial action at 410. In an example, compliance circuitry 304 is designed to preclude application of power to functional circuitry 302 unless/until processor 306 successfully authenticates second instructions 322.

At 414, processor 306 enables functional circuitry 302.

At 416, processor 306 monitors resource metric(s) 310 of functional circuitry 302 via global control ring 312, based on resource metric monitoring instructions 330.

At 418, processor 306 compares resource metric(s) 310 to resource restriction(s) 332 based on resource metric monitoring instructions 330.

At 420, if resource metric(s) 310 exceeds resource restriction(s) 332, processing proceeds to 422, where processor 306 initiates a remedial action (e.g., disabling functional circuitry 302 or a portion thereof). Otherwise, processor 306 continues monitoring resource metric(s) 310 at 416.

In an example, a resource restriction 332 may include a per function resource restriction. The per function resource restriction may relate to ADCs. Examples are provided in Table 1.

TABLE 1

| Resolution (number of bits) | Maximum Sample Rate |
|---|---|
| 8 or more, but less than 10 | 1.3 giga bits per second (GSPS) |
| 10 or more, but less than 11 | 600 mega samples per bit (MSPS) |
| 12 or more, but less than 12 | 400 MSPS |

In this example, processor 306 may monitor sample rates of ADCs 214 (FIG. 2) at 416, and may compare the sample rates to the maximum sample rates based on resolutions of the respective ADCs at 418. If the sample rate of any of ADCs 214 exceeds a sample rate restriction, processing proceeds to 422.

In another example, a resource restriction 332 may specify an aggregate resource restriction, such as an aggregate one-way peak serial transceiver data rate. In this example, at 416, processor 306 may monitor data rates (e.g., line rate counters) of transceivers 218, and may determine an aggregate data rate based on resource metric aggregate instructions 334. If the aggregate data rate of transceivers 218 exceeds the aggregate resource restriction, processing proceeds to 422.

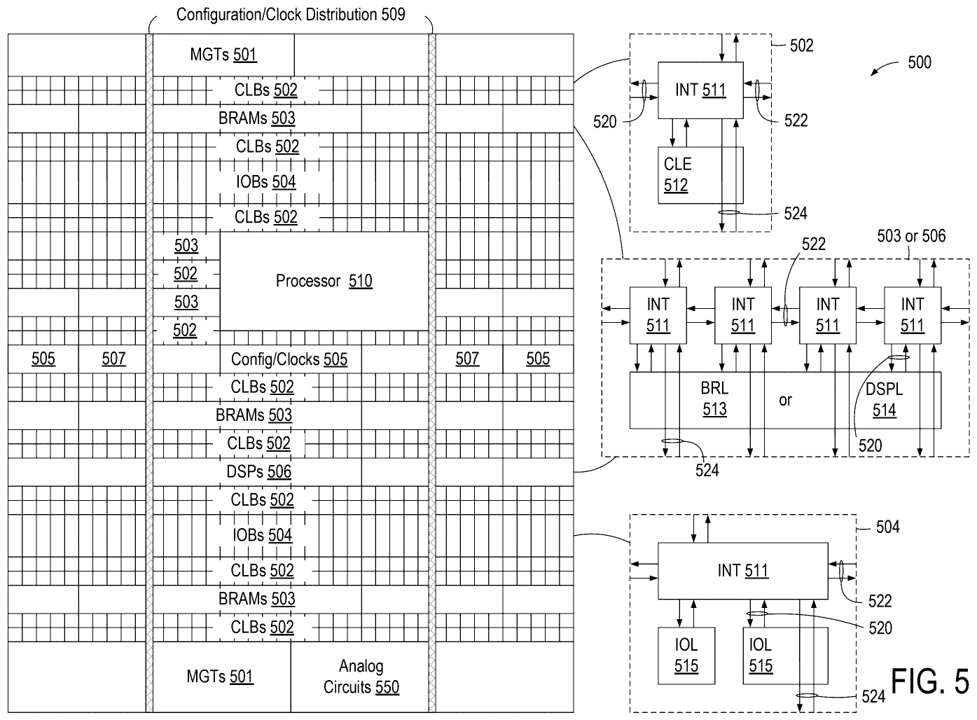

One or more of systems 100, 200, and 300, or a portion thereof, may include one or more of a variety of types of configurable circuit blocks, such as described below with reference to FIG. 5. FIG. 5 is a block diagram of configurable circuitry 500, including an array of configurable or programmable circuit blocks or tiles, according to an embodiment. The example of FIG. 5 may represent a field programmable gate array (FPGA) and/or other IC device(s) that utilizes configurable interconnect structures for selectively coupling circuitry/logic elements, such as complex programmable logic devices (CPLDs).

In the example of FIG. 5, the tiles include multi-gigabit transceivers (MGTs) 501, configurable logic blocks (CLBs) 502, block random access memory (BRAM) 503, input/output blocks (IOBs) 504, configuration and clocking logic (Config/Clocks) 505, digital signal processing (DSP) blocks 506, specialized input/output blocks (I/O) 507 (e.g., configuration ports and clock ports), and other programmable logic 508, which may include, without limitation, digital clock managers, analog-to-digital converters, and/or system monitoring logic. The tiles further includes a dedicated processor 510.

One or more tiles may include a programmable interconnect element (INT) 511 having connections to input and output terminals 520 of a programmable logic element within the same tile and/or to one or more other tiles. A programmable INT 511 may include connections to interconnect segments 522 of another programmable INT 511 in the same tile and/or another tile(s). A programmable INT 511 may include connections to interconnect segments 524 of general routing resources between logic blocks (not shown). The general routing resources may include routing channels between logic blocks (not shown) including tracks of interconnect segments (e.g., interconnect segments 524) and switch blocks (not shown) for connecting interconnect segments. Interconnect segments of general routing resources (e.g., interconnect segments 524) may span one or more logic blocks. Programmable INTs 511, in combination with general routing resources, may represent a programmable interconnect structure.

A CLB 502 may include a configurable logic element (CLE) 512 that can be programmed to implement user logic. A CLB 502 may also include a programmable INT 511.

A BRAM 503 may include a BRAM logic element (BRL) 513 and one or more programmable INTs 511. A number of interconnect elements included in a tile may depends on a height of the tile. A BRAM 503 may, for example, have a height of five CLBs 502. Other numbers (e.g., four) may also be used.

A DSP block 506 may include a DSP logic element (DSPL) 514 in addition to one or more programmable INTs 511. An IOB 504 may include, for example, two instances of an input/output logic element (IOL) 515 in addition to one or more instances of a programmable INT 511. An I/O pad connected to, for example, an I/O logic element 515, is not necessarily confined to an area of the I/O logic element 515.

In the example of FIG. 5, config/clocks 505 may be used for configuration, clock, and/or other control logic. Vertical columns 509 may be used to distribute clocks and/or configuration signals.

A logic block (e.g., programmable of fixed-function) may disrupt a columnar structure of configurable circuitry 500. For example, processor 510 spans several columns of CLBs 502 and BRAMs 503. Processor 510 may include one or more of a variety of components such as, without limitation, a single microprocessor to a complete programmable processing system of microprocessor(s), memory controllers, and/or peripherals.

In FIG. 5, configurable circuitry 500 further includes analog circuits 550, which may include, without limitation, one or more analog switches, multiplexers, and/or de-multiplexers. Analog switches may be useful to reduce leakage current.

FIG. 5 is provided for illustrative purposes. Configurable circuitry 500 is not limited to numbers of logic blocks in a row, relative widths of the rows, numbers and orderings of rows, types of logic blocks included in the rows, relative sizes of the logic blocks, illustrated interconnect/logic implementations, or other example features of FIG. 5.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A system, comprising:
functional circuitry; and
compliance circuitry configured to monitor a resource metric of the functional circuitry and perform a remedial action if the resource metric exceeds a resource restriction, based on a hardware-embedded authentication metric.

2. The system of claim 1, wherein the resource restriction comprises a per element resource restriction, and wherein the compliance circuitry is further configured to:
monitor the resource metric of a corresponding element of the functional circuitry; and
perform the remedial action if the resource metric of the element of the functional circuitry exceeds the per element resource restriction.

3. The system of claim 2, wherein the per element resource restriction comprises multiple sample rate restrictions, and wherein the compliance circuitry is further configured to:
monitor a sample rate of an analog-to-digital converter (ADC) of the functional circuitry;
identify one of the sample rate restrictions based on a resolution of the ADC; and
perform the remedial action if the sample rate of the ADC exceeds the identified sample rate restriction.

4. The system of claim 1, wherein the resource restriction comprises an aggregate resource restriction, and wherein the compliance circuitry is further configured to:
monitor multiple sources of the resource metric to obtain multiple measures of the resource metric;
determine an aggregate resource metric based on the multiple measures of the resource metric; and
perform the remedial action if the aggregate resource metric exceeds the aggregate resource restriction.

5. The system of claim 4, wherein the resource restriction further comprises an aggregate transceiver data rate restriction, and wherein the compliance circuitry is further configured to:
monitor data rates of multiple transceivers of the functional circuitry;
determine an aggregate data rate based on the data rates of the transceivers; and
perform the remedial action if the aggregate data rate exceeds the aggregate transceiver data rate restriction.

6. The system of claim 1, wherein the resource restriction comprises a total processing performance (TPP) resource restriction, and wherein the compliance circuitry is further configured to:
monitor resource metrics of an array of processing elements;
determine an aggregate resource metric based on the monitored resource metrics of the array of processing elements; and
perform the remedial action if the aggregate resource metric exceeds the aggregate transceiver data rate restriction.

7. The system of claim 1, wherein:
the functional circuitry comprises multiple circuit blocks configured to communicate with one another via a first communication infrastructure; and
the compliance circuitry is further configured to monitor the resource metric via a second communication infrastructure.

8. A system, comprising:
a processor;
first storage circuitry encoded with first instructions and an authentication metric; and
second storage circuitry encoded with second instructions;
wherein the processor is configured to execute the first instructions from the first storage circuitry when the processor is powered-up;
wherein the first instructions, when executed by the processor, cause the processor to authenticate the second instructions based on the authentication metric, and execute the second instructions from the second storage circuitry if the processor authenticates the second instructions; and
wherein the second instructions, when executed by the processor, cause the processor to monitor a resource metric of functional circuitry and perform a remedial action if the monitored resource metric exceeds a resource restriction.

9. The system of claim 8, wherein:
the first storage circuitry is non-reprogrammable; and
the second storage circuitry is reprogrammable.

10. The system of claim 8, wherein the second instructions, when executed by the processor, cause the processor to:
enable operation of the functional circuitry.

11. The system of claim 8, wherein the resource restriction comprises a per element resource restriction, and wherein the second instructions, when executed by the processor, further cause the processor to:
monitor the resource metric of a corresponding element of the functional circuitry; and
perform the remedial action if the resource metric of the element of the functional circuitry exceeds the per element resource restriction.

12. The system of claim 8, wherein the resource restriction comprises an aggregate resource restriction, and wherein the second instructions, when executed by the processor, further cause the processor to:
monitor multiple sources of the resource metric to obtain multiple measures of the resource metric;
determine an aggregate resource metric based on the multiple measures of the resource metric; and
perform the remedial action if the aggregate resource metric exceeds the aggregate resource restriction.

13. The system of claim 8, wherein:
the functional circuitry comprises multiple circuit blocks configured to communicate with one another via a first communication infrastructure; and
the processor is further configured to monitor the resource metric of the functional circuitry via a second communication infrastructure.

14. A method, comprising:
monitoring a resource metric of functional circuitry by compliance circuitry based on a hardware-embedded authentication metric; and
performing a remedial action, by the compliance circuitry, if the monitored resource metric exceeds a resource restriction.

15. The method of claim 14, wherein the resource restriction comprises a per element resource restriction, and wherein:
the monitoring comprises monitoring the resource metric of a corresponding element of the functional circuitry; and
the performing comprises performing the remedial action if the resource metric of the element of the functional circuitry exceeds the per element resource restriction.

16. The method of claim 15, wherein the per element resource restriction comprises multiple sample rate restrictions, and wherein:
the monitoring further comprises monitoring a sample rate of an analog-to-digital converter (ADC) of the functional circuitry;
the method further comprises identifying one of the sample rate restrictions based on a resolution of the ADC; and
the performing further comprises performing the remedial action if the sample rate of the ADC exceeds the identified sample rate restriction.

17. The method of claim 14, wherein the resource restriction comprises an aggregate resource restriction, and wherein;
the monitoring comprises monitoring multiple sources of the resource metric to obtain multiple measures of the resource metric;
the method further comprises determining an aggregate resource metric based on the multiple measures of the resource metric; and
the performing comprises performing the remedial action if the aggregate resource metric exceeds the aggregate resource restriction.

18. The method of claim 17, wherein the aggregate resource restriction comprises an aggregate data rate restriction, and wherein:
the monitoring further comprises monitoring data rates of multiple transceivers of the functional circuitry;
the method further comprises determining an aggregate data rate based on the data rates of the transceivers; and
the performing further comprises performing the remedial action if the aggregate data rate exceeds the aggregate data rate threshold.

19. The method of claim 14, wherein the compliance circuitry comprises a processor, non-reprogrammable storage circuitry encoded with the authentication metric and first instructions, and reprogrammable storage circuitry encoded with second instructions, the method further comprising, by the processor:
executing the first instructions from the non-reprogrammable storage circuitry, on power-up of the processor, wherein the first instructions, when executed by the processor, cause the processor to authenticate the second instructions based on the authentication metric, and initiate execution of the second instructions from the reprogrammable storage circuitry if the processor authenticates the second instructions; and
executing the second instructions, if the processor successfully authenticates the second instructions, wherein the second instructions, when executed by the processor, cause the processor to monitor the resource metric of the functional circuitry, and perform the remedial action if the resource metric exceeds the resource restriction.

20. The method of claim 16, further comprising:
precluding operation of the functional circuitry if the processor does not successfully authenticate the second instructions.
